(19) United States
(12) Patent Application Publication
(10) Pub. No.: US 2004/0150960 A1
(43) Pub. Date: Aug. 5, 2004

(54) Subrack with a terminal strip for receiving connecting components

(76) Inventors: Christian Polacek-Attenberger, Munchen (DE); Siegwald Schuster, Grafelfing (DE)

Correspondence Address: BELL, BOYD & LLOYD, LLC, P. O. BOX 1135, CHICAGO, IL, 60690-1135, US

(21) Appl. No.: 10/479,445

(22) PCT Filed: May 2, 2002
(86) PCT No.: PCT/DE02/01595

(30) Foreign Application Priority Data
May 29, 2001 (DE) 101 26 112.8

(51) Int. Cl. H05K 7/14

(52) U.S. Cl. 361/730; 361/823

(57) ABSTRACT

The subrack has a slot for the terminal strip (4) embodied as a self-supporting, autonomous modular unit. By means of the mirror-image arrangement of the fixing points in the subrack, the terminal strip (4) can be selectively assembled in such a way that external lines coming from the front or back side of the subrack can be connected to connecting components (5) of the terminal strip (4).

The invention relates to a subrack for electrical slide-in modules with a terminal strip mounted between side panels of the subrack for receiving connecting components for external lines.

U.S. Pat. No. 4,947,288 A discloses a subrack on the rear side of which a self-supporting wiring backplane can be mounted. This backplane has connecting components on its internal side for the modules inserted from the front. Wiring backplanes of this type are customarily also equipped on their external side with connecting components for external lines.

It is customary (see DE 4420983 A) to equip the underside of subracks for transmission networks with a termination panel on which various connecting components for connecting external electrical lines are arranged, with said components being secured to supports integrated in the subrack. A requirement of various users is for the connecting components to be arranged with varying orientation. This results in the production in some cases of subracks with termination panels on which the external cables can be plugged from the rear. Other subracks are embodied such that the external lines can be connected from the front.

The object of the invention is to reduce the complexity of producing the subracks.

This object is achieved by the invention according to the claim. The termination panel is now combined in a separate modular unit that is suitable for both front and rear mounting in the subrack without any modifications. This is facilitated by the subrack's being, for instance, fitted with structural elements embodied as bore holes in turn embodied in downward protruding side panels of the subrack for both front and rear mounting. Consequently only one type of subrack is required in large volumes. In order to minimize the bending load of the supporting body it is further advantageous to provide fixing holes in the center section of the top side of the supporting body so it can be additionally connected to frame sections of the subrack.

The invention is explained in greater detail below with reference to the exemplary embodiment shown in the drawing.

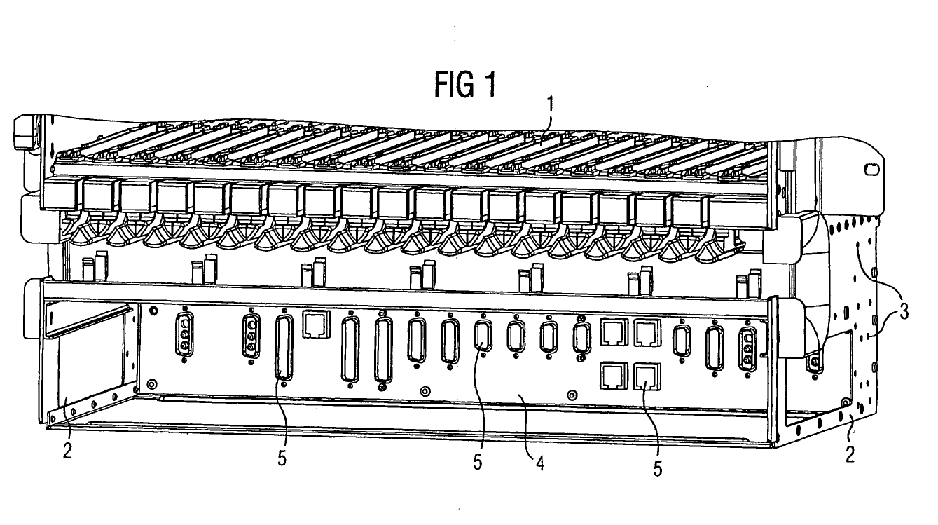

FIG. 1 shows a partial perspective front view of a subrack with a terminal strip which can be operated from the front,

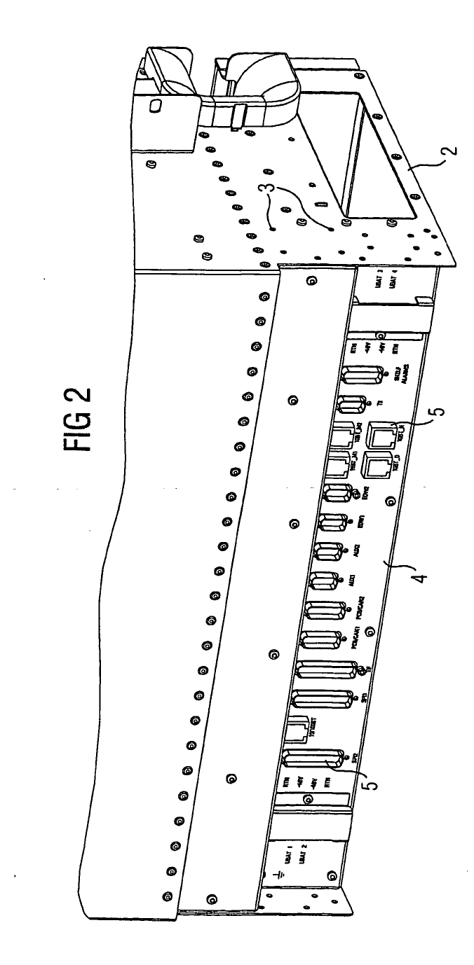

FIG. 2 shows a rear view of the subrack according to FIG. 1 with a terminal strip oriented to the rear, and

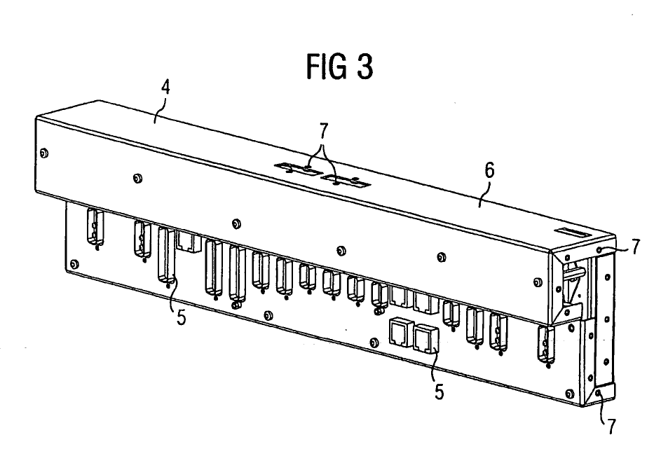

FIG. 3 shows a separate view of the terminal strip according to FIG. 1 or 2.

According to FIG. 1, a subrack for slide-in modules has been equipped with guides 1, shown on their underside, for the insertion of modules. Side panels 2 of the subrack have been extended in length beyond the underside of the guide rails 1 and provided with fixing holes 3 for a terminal strip 4 screwed in position between the side panels 2. The terminal strip 4 is equipped with various connecting components 5 which are oriented toward the front and into which appropriate plug connectors of external lines can be plugged from this side.

The same subrack has additional fixing holes 3 arranged in mirror-image fashion to the others. According to FIG. 2, the terminal strip 4 has been screwed into position in these additional holes in reverse orientation toward the rear of the subrack.

FIG. 3 shows the terminal strip 4 with a supporting body 6 formed from sheet metal. This body has sufficient intrinsic stability for the terminal strip 4 to be supplied as a separate modular unit and, as required, applied with the orientation of FIG. 1 or of FIG. 2. The supporting body 6 has mounting holes 7 which coincide with the fixing holes 3. Arranged in the center section of the top side of the supporting body 6 are additional mounting holes 7 by means of which the terminal strip 4 can be secured to the subrack and stabilized.

1. Subrack for electrical slide-in modules with a terminal strip (4) mounted between side panels (2) of the subrack for receiving connecting components (5) for external lines, characterized in that
the terminal strip (4) embodied as a self-supporting unit has an intrinsically structurally stable supporting body (6),
the subrack and the supporting body (6) have structural elements (such as 3,7) arranged in reciprocally mirror-image fashion for securing the supporting body (6), and
the supporting body (6) can be optionally mounted with the connecting components (5) having a front or rear orientation.
